(19) United States
(12) Patent Application Publication
(10) Pub. No.: US 2005/0157565 A1
(43) Pub. Date: Jul. 21, 2005

(54) Semiconductor device for detecting memory failure and method thereof

(76) Inventor: Hoi-Jin Lee, Sungnam-si (KR)

Correspondence Address: HARNESS, DICKEY & PIERCE, P.L.C., P.O. BOX 8910, RESTON, VA, 20195, US

(21) Appl. No.: 11/032,112

(22) Filed: Jan. 11, 2005

(30) Foreign Application Priority Data
Jan. 15, 2004 (JP) 2004-02998

(51) Int. Cl. G11C 5/00

(52) U.S. Cl. 365/189.05

(57) ABSTRACT

A semiconductor device for testing memory, including a BIST controller for testing a plurality of memory devices, an address and control signal generator for generating address and control signals for reading data from the plurality of memory devices, a test data generator for generating test data, and a fail detector for determining memory failure. Another semiconductor device for testing at least one of a plurality of memory devices, including a BIST controller for testing a plurality of memory devices, an address and control signal generator for generating address and control signals for reading data from the plurality of memory devices, a test data generator for generating test data, a reference data generator for generating reference data, and a fail detector for determining memory failure. A method of determining memory failure, including writing data to a plurality of memory devices, reading the data from the plurality of memory devices, comparing corresponding addresses of the read data simultaneously, outputting a single fail signal when the comparing step determines at least one of the read data from the plurality of memory devices as not being equal. A semiconductor device for testing memory, including a BIST controller for testing a plurality of memory devices, an address and control signal generator for generating address and control signals for reading data from the plurality of memory devices, a test data generator for generating test data, a reference data generator for generating reference data, a selection circuit for selecting the read data from one of the plurality of memory devices, and a comparator for comparing the read data from one of the plurality of memory devices with the reference data. A semiconductor device for testing memory, including a BIST controller for testing a plurality of memory devices, an address and control signal generator for generating address and control signals for reading data from the plurality of memory devices, a test data generator for generating test data, and a single comparison unit for determining memory failure in at least two of the plurality of memory devices. A method of determining memory failure, including writing data to a plurality of memory devices, reading the data from the plurality of memory devices, comparing corresponding addresses of the read data of at least two of the plurality of memory devices in a single comparison unit.

### CROSS REFERENCE TO RELATED APPLICATIONS

This application claims the priority of Korean Patent Application 2004-02998 filed on Jan. 15, 2004, in the Korean Intellectual Property Office, the disclosure of which is incorporated herein by reference in its entirety.

### BACKGROUND OF THE INVENTION

1. Field of the Invention

The present invention relates generally to semiconductor devices, and more particularly, to a semiconductor device for detecting memory failure.

2. Description of Prior Art

Built-In Self-Test (BIST) circuits are self-diagnostic circuits for testing semiconductor memory devices. Test data may be applied to a BIST circuit in order to test semiconductor memory devices. The BIST circuit may compare data read from the semiconductor memory device with reference data, and may determine whether a memory failure exists in the semiconductor memory deviced based on the comparison. As memory sizes increase in semiconductor memory devices, an increase may also occur in the area of BIST circuits.

FIG. 1 illustrates a BIST circuit for testing memory according to conventional methods. Referring to FIG. 1, the BIST circuit 1 may include a BIST controller 100, an address and control signal generator 110 a test data generator 120, a reference data generator 130, and a comparator 140. The BIST controller 100 may generate a control signal which may be received by each of the address and control signal generator 110, the test data generator 120 and the reference data generator 130.

The address and control signal generator 110 may output a signal for determining access to/from the first memory device 11, second memory device 12 and/or third memory device 13.

The test data generator 120 may generate test data which may be written to corresponding addresses of the first memory device 11, second memory device 12 and third memory device 13. For example, D1N1[0]=D1N2[0]=D1N3[0], D1N1[1]=D1N2[1]=D1N3[1], . . . , D1N1[7]=D1N2[7]=D1N3[7], D1N1[8]=D1N2[8], . . . , D1N3[31]. In this case, D1N1[0] may refer to memory address “0”, or the lowest bit, of the first memory device 11. In addition, D1N1[0]=D1N2[0]=D1N3[0] may indicate that data written to memory address “0” of the first memory device 11, second memory device 12 and third memory device 13, respectively, have the same value.

The reference data generator 130 may output reference data which may be sent to a comparator 140. The reference data may be equivalent to test data written to the first memory device 11, second memory device 12 and third memory device 13. The reference data generator 130 may include a plurality of flipflops for latching the reference data. The number of the plurality flipflops in the reference data generator 130 may scale with the number of input/output (I/O) terminals of the first memory device 11, second memory device 12 and third memory device 13. For example, as shown in FIG. 1, the reference data generator 130 may include 32 flipflops in order to latch reference data for comparison with the output of the first memory device 11, second memory device 12 and third memory device 13.

The comparator 140 may compare data read from the first memory device 11, second memory device 12 and third memory device 13 with reference data generated received from the reference data generator 130. The comparator 140 may determine whether a memory failure occurs based on the comparison. The comparator 140 may include a first comparator 141, a second comparator 142 and a third comparator 143. The first comparator 141 may determine whether the output of the first memory device 11 indicates a memory failure. The second comparator 142 may determine whether the output of the second memory device 12 indicates a memory failure. The third comparator 143 may determine whether the output of the third memory device 13 indicates a memory failure. In all of the above described conventional devices, a comparison result of compared data not being equal may indicate a memory failure.

The first comparator 141, second comparator 142 and third comparator 143 may include flipflops for latching data from the first memory 11, second memory device 12 and third memory device 13, respectively. As shown in FIG. 1, the first comparator 141 may include 32 flipflops, the number of flip flops being related to a number of output terminals of the first memory device 11. As shown in FIG. 1, the second comparator 142 may include 24 flipflops, the number of flipflops being related to a number of output terminals of the second memory device 12. As shown in FIG. 1, the third comparator 143 may include 8 flipflops, the number of flip flops being related to a number of output terminals of the third memory device 13. Therefore, the comparator 140 may include a total of 64 flipflops between the first comparator 141, second comparator 142 and third comparator 143.

By conventional methods, as larger amounts of memory become necessary for testing with a BIST circuit, the number of flipflops included in the BIST circuit may increase. An increased number of flipflops in a BIST circuit may increase the area of the BIST circuit significantly.

### BRIEF DESCRIPTION OF THE DRAWINGS

The present invention will become more apparent by describing in detail exemplary embodiments thereof with reference to the attached drawings in which:

FIG. 1 illustrates a BIST circuit for testing memory according to conventional methods.

FIG. 2 illustrates a schematic block diagram of a BIST circuit for testing memory according to an exemplary embodiment of the present invention.

FIG. 3 illustrates a schematic diagram of a comparator according to an exemplary embodiment of the present invention.

FIG. 4 illustrates a schematic diagram of a BIST circuit according to another exemplary embodiment of the present invention.

FIG. 5 illustrates a schematic circuit diagram of the fail detector of FIG. 4 according to an exemplary embodiment of the present invention.

FIG. 6 illustrates a schematic diagram of a BIST circuit according to another exemplary embodiment of the present invention.

FIG. 7 illustrates a schematic circuit diagram of the fail detector of FIG. 6 according to an exemplary embodiment of the present invention.

### SUMMARY OF THE INVENTION

An exemplary embodiment of the present invention is a semiconductor device for testing memory, including a BIST controller for testing a plurality of memory devices, an address and control signal generator for generating address and control signals for reading data from the plurality of memory devices, a test data generator for generating test data, and a fail detector for determining memory failure.

Another exemplary embodiment of the present invention is a semiconductor device for testing at least one of a plurality of memory devices, including a BIST controller for testing a plurality of memory devices, an address and control signal generator for generating address and control signals for reading data from the plurality of memory devices, a test data generator for generating test data, a reference data generator for generating reference data, and a fail detector for determining memory failure.

Another exemplary embodiment of the present invention is a method of determining memory failure, including writing data to a plurality of memory devices, reading the data from the plurality of memory devices, comparing corresponding addresses of the read data simultaneously, outputting a single fail signal when the comparing step determines at least one of the read data from the plurality of memory devices as not being equal.

Another exemplary embodiment of the present invention is a semiconductor device for testing memory, including a BIST controller for testing a plurality of memory devices, an address and control signal generator for generating address and control signals for reading data from the plurality of memory devices, a test data generator for generating test data, a reference data generator for generating reference data, a selection circuit for selecting the read data from one of the plurality of memory devices, and a comparator for comparing the read data from one of the plurality of memory devices with the reference data.

Another exemplary embodiment of the present invention is a semiconductor device for testing memory, including a BIST controller for testing a plurality of memory devices, an address and control signal generator for generating address and control signals for reading data from the plurality of memory devices, a test data generator for generating test data, and a single comparison unit for determining memory failure in at least two of the plurality of memory devices.

Another exemplary embodiment of the present invention is a method of determining memory failure, including writing data to a plurality of memory devices, reading the data from the plurality of memory devices, comparing corresponding addresses of the read data of at least two of the plurality of memory devices in a single comparison unit.

### DETAILED DESCRIPTION OF THE EXEMPLARY EMBODIMENTS OF THE INVENTION

Hereinafter, exemplary embodiments of the present invention will be described in detail with reference to the accompanying drawings.

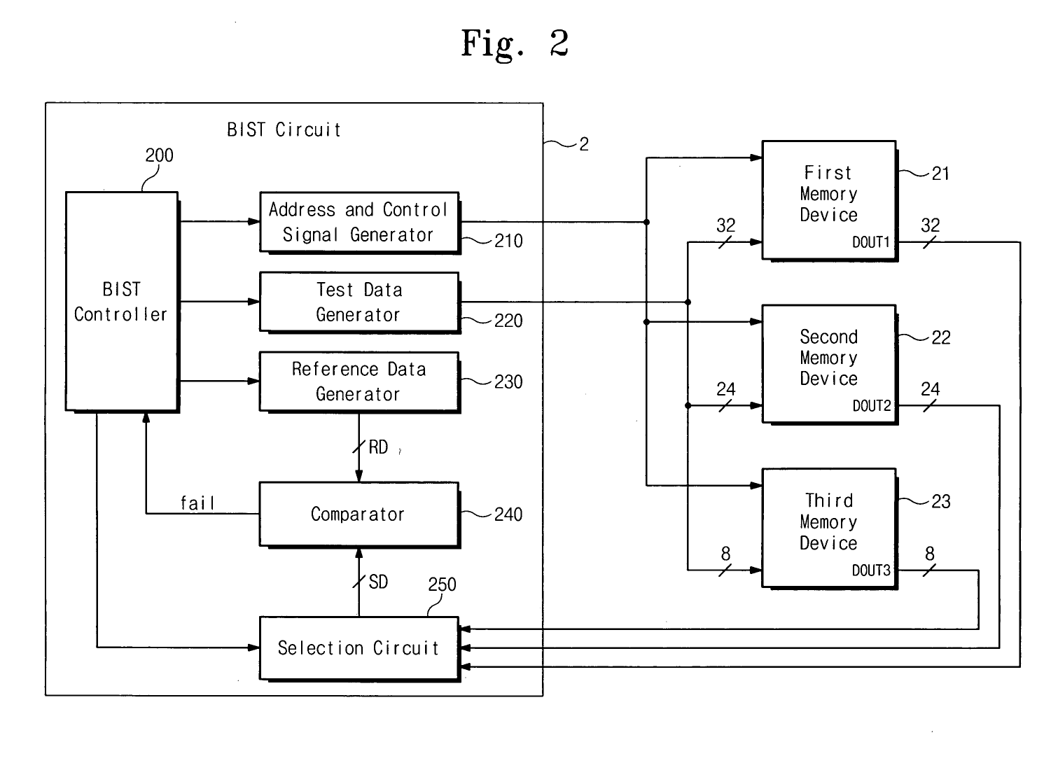

FIG. 2 illustrates a schematic block diagram of a BIST circuit for testing memory according to an exemplary embodiment of the present invention. Referring to FIG. 2, the BIST circuit may include a BIST controller 200, an address and control signal generator 210, a test data generator 220 a reference data generator 230, a comparator 240 and a selection circuit 250.

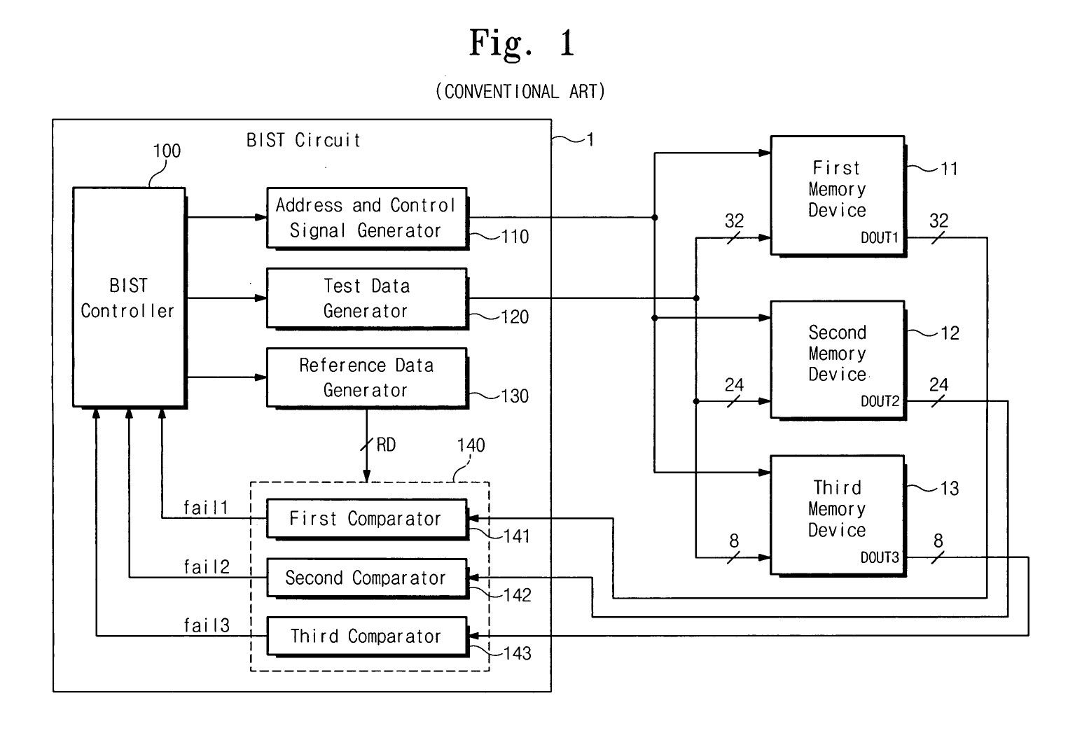

The BIST controller 200, the address and control signal generator 210, the test data generator 220 and the reference data generator 230 may function similarly as compared to the BIST controller 100, address and control signal generator 110, and test data generator 120, respectively, of FIG. 1.

In an exemplary embodiment of the present invention, the selection circuit 250 may select one of the first memory device 21, second memory device 22, and third memory device 23 based on a control signal received from the BIST controller 200. The selected memory device may output data to the comparator 240. The selection circuit 250 may be implemented by any well-known selection circuit. For example, the selection circuit 250 may be a multiplexer.

The comparator 240 may compare selected data (SD) from the selected memory selected among the first memory device 21, second memory device 22, and third memory device 23 with reference data (RD) from the reference data generator 230. The comparator 240 may determine whether the RD and the SD are equivalent in order to determine if memory failure has occurred. The comparator 240 may output a fail signal to the BIST controller if the SD and the RD are not equivalent.

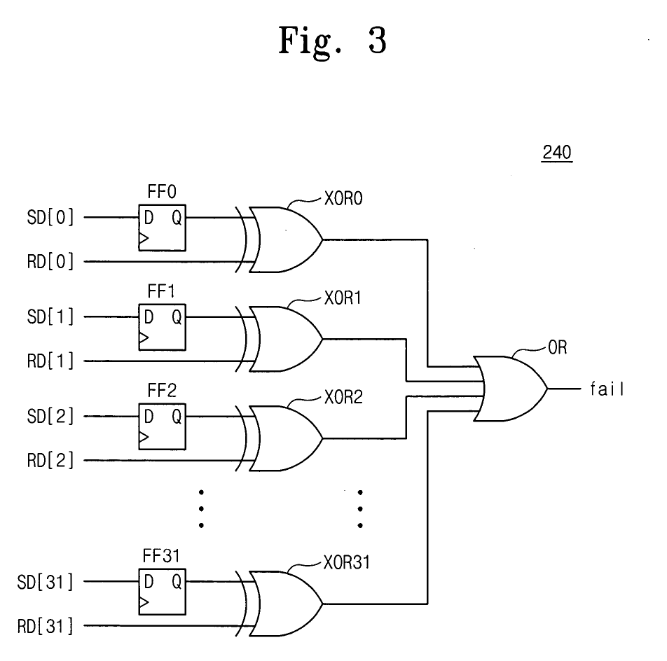

FIG. 3 illustrates a schematic diagram of a comparator 240 according to an exemplary embodiment of the present invention. The comparator 240 may include flipflops FF0-FF31, XOR gates XOR1-XOR31 and an OR gate.

In an exemplary example, it may be assumed that the comparator 240 receives data from the first memory device 21 based on a selection by selection circuit 250. The flipflops FF0-FF31 may temporarily latch data SD[0]-SD[31] from the first memory device 21. The latched data in FF0-FF31 may be synchronized with a clock signal before being output to XOR gates XOR0-XOR31. The XOR gates XOR0-XOR31 may receive SD[0]-SD[31] and RD[0]-RD[31], RD[0]-RD[31] being received from the reference data generator 230. If values input into an XOR gate are equivalent, the XOR gate may output a logic “0”. If values entered into an XOR gate are not equivalent, the XOR gate may output a logic “1”.

The OR gate may receive the output of each of the XOR gates XOR0-XOR31. The OR gate may output a logic “1”, indicating a memory failure, if at least one of XOR0-XOR31 outputs a logic “1”.

In an exemplary embodiment of the present invention, the comparator 240 may be designed to scale with the memory device having a largest number of I/O terminals. For example, as shown in FIG. 2, the first memory device 21 has the largest number of I/O terminals (i.e., 32 I/O terminals) among the first memory device 21, second memory device 22 and third memory device 23. The comparator 240, as shown in FIG. 3, may be designed to receive data from the I/O terminals of first memory device 21, while also being suitable to receive lesser amounts of data from the second memory device 22 and/or third memory device 23.

In another exemplary embodiment of the present invention, referring again to FIG. 2, the BIST circuit 2 may include a single comparator, in contrast to FIG. 1. Accordingly, the BIST circuit 2 may require fewer flipflops than the BIST circuit 1 of FIG. 1. In FIG. 2, the BIST circuit 2 may require 32 flipflops while the BIST circuit of FIG. 1 may require 64 flipflops.

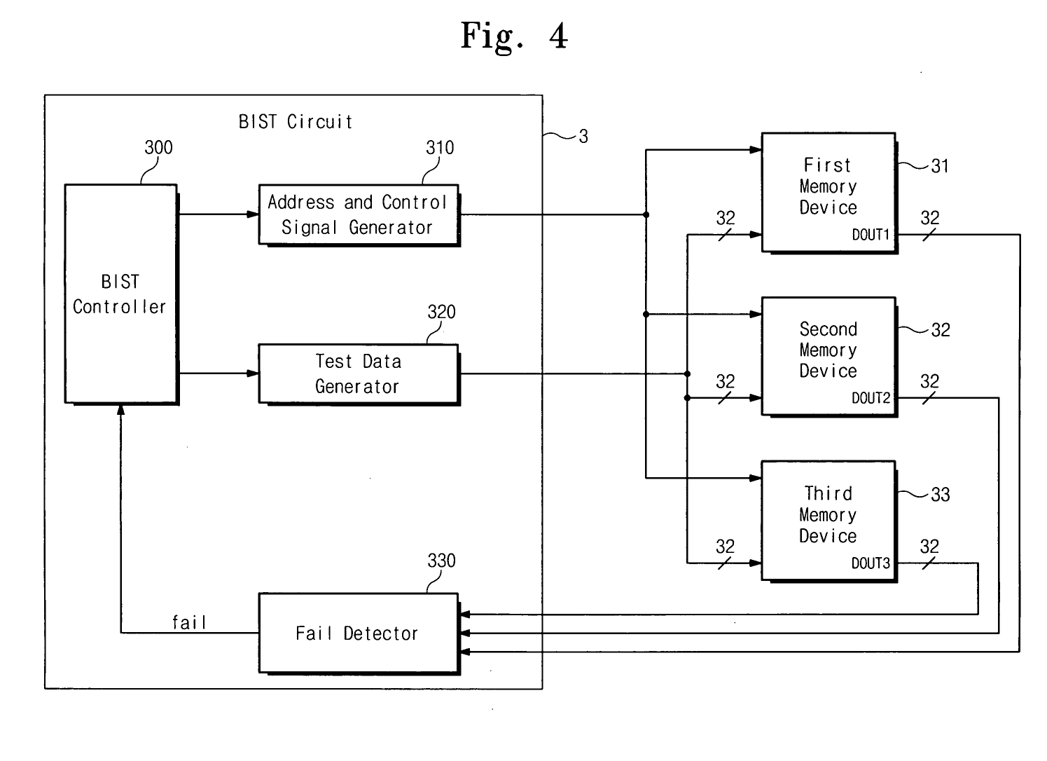

FIG. 4 illustrates a schematic diagram of a BIST circuit according to another exemplary embodiment of the present invention. The BIST circuit 3 may test first memory device 31, second memory device 32 and/or third memory device 33 for memory failure. It will be appreciated that, as shown in FIG. 4, the first memory device 31, second memory device 32, and third memory device 33 each have 32 I/O terminals. However, it is understood that each of the memory devices 31, 32 and 33 may have any number of I/O terminals. It is further understood that additional memory devices may be added similar to first memory device 31, second memory device 32 and third memory device 33.

In an exemplary example, referring to FIG. 4, it may be assumed that the first memory device 31, second memory device 32, and third memory device 33 each have 32 I/O terminals. Further, assume test data is written to corresponding addresses among first memory device 31, second memory device 32 and third memory device 33. In this example, D1N1[0]=D1N2[0]=D1N3[0], D1N1[1]=D1N2[1]=D1N3[1], . . . , D1N1[30]=D1N2[30]=D1N3[30], D1N1[31]=D1N2[31]=D1N3[31].

Referring to FIG. 4, the BIST circuit 3 may include a BIST controller 300, an address and control signal generator 310, a test data generator 320 and a fail detector 330. The BIST circuit 3 may perform a test operation with respect to the first memory device 31, second memory device 32, and third memory device 33 without a reference data generator and/or a comparator.

The BIST controller 300, the address and control signal generator 310, and the test data generator 320 may function similarly as compared to the BIST controller 100, address and control signal generator 110, and test data generator 120 of FIG. 1.

The fail detector 330 may determine whether data read from corresponding addresses of first memory device 31, second memory device 32 and third memory device 33 are equivalent. If the fail detector 330 determines that the data read from corresponding addresses of first memory device 31, second memory device 32 and third memory device 33 are not equivalent, the fail detector 330 may generate a fail signal.

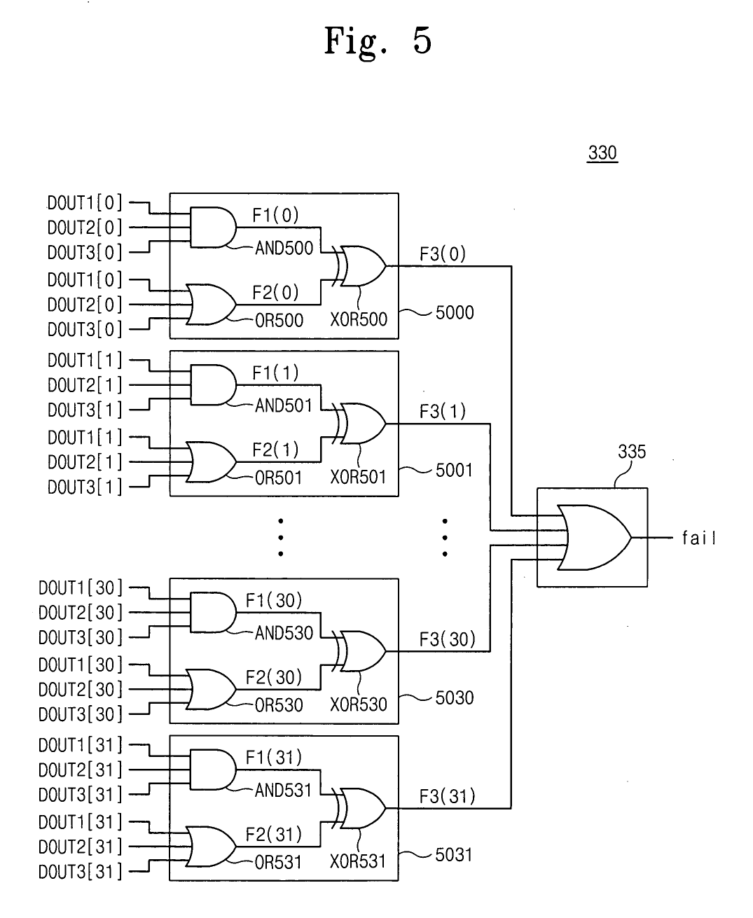

FIG. 5 illustrates a schematic circuit diagram of the fail detector of FIG. 4 according to an exemplary embodiment of the present invention. The fail detector 330 may include combinational logic circuits (CLC) 5000-5031, and an OR gate 335. The CLC 5000-5031 may receive data read from the first memory device 31, second memory device 32 and third memory device 33. The OR gate 335 may receive output from the CLC 5000-5031 in order to determine whether to generate a fail signal.

In an exemplary embodiment of the present invention, the CLC 5000-3031 may include AND gates AND500-AND531, OR gates OR500-OR531, and XOR gates XOR500-XOR531, respectively. The OR gate 335 may include a single OR gate.

An example of an exemplary embodiment of the present invention will now be described. The CLC 5000 may receive DOUT1[0], DOUT2[0] and DOUT3[0]. DOUT1[0], DOUT2[0] and DOUT3[0] may represent the lowest bit from the first memory 31, second memory device 32 and third memory device 33, respectively.

According to this example, if each of DOUTI [0], DOUT2[0] and DOUT3[0] is logic “0”, output F1(0) of AND gate AND500 and output F2(2) of OR gate OR500 may each be logic “0”. Further, the output F3(0) of XOR gate XOR500 may be logic “0”.

According to this example, if each of DOUT1[0], DOUT2[0] and DOUT3[0] is logic “1”, output F1(0) of AND gate AND500 and output F2(2) of OR gate OR500 may each be logic “1”. Further, the output F3(0) of XOR gate XOR500 may be logic “1”.

According to this example, if at least one but not all of DOUT1[0], DOUT2[0] and DOUT3[0] is logic “1”, output F1(0) of AND gate AND500 may be logic “0” and output F2(2) of OR gate OR500 may be logic “1”. Further, the output F3(0) of XOR gate XOR500 may be logic “1”.

In another exemplary embodiment of the present invention, outputs F3(0)-F3(31) of XOR gates XOR500-XOR531, respectively, may be output to OR gate 335. Therefore, if at least one of outputs F3(0)-F3(31) is logic “1”, the output of OR gate 335, which may also be referred to as the fail signal, also may be logic “1”, indicating memory failure.

In another exemplary embodiment of the present invention, referring to FIG. 4, the number of I/O terminals of the first memory device 31, second memory device 32, and third memory device 33 may be equivalent. The BIST circuit 3 may determine whether data read from corresponding addresses of the first memory device 31, second memory device 32, and third memory device 33 are equivalent. Therefore, the BIST circuit 3 may determine whether memory failure has occurred by comparing data from corresponding addresses of the first memory device 31, second memory device 32, and third memory device 33.

In another exemplary embodiment of the present invention, the number of I/O terminals of first memory device 31, second memory device 32 and third memory device 33 may not be equivalent. For example, the number of I/O terminals of the first memory device 31 and second memory device 32 may each be 32, and the number of I/O terminals of the third memory device 33 may be 24. The BIST circuit 3 may determine whether memory failure has occurred by comparing data from corresponding addresses of the first memory device 31, second memory device 32, and third memory device 33, since two or more data read from two or more of first memory device 31, second memory device 32 and third memory device 33 may be sufficient to determine memory failure has occurred.

In another exemplary embodiment of the present invention, the BIST circuit 3 may reduce a test time for memory failure. The test time for memory failure may be reduced through a simultaneous testing of each of first memory device 31, second memory device 32 and third memory device 33 by the BIST circuit 3. Simultaneous testing may be achieved with the BIST circuit 3 with the omission of a reference data generator and a comparator, and further with the inclusion of fail detector 330. Further, the omission of the reference data generator and the comparator and inclusion of fail detector 330 may reduce the number of flipflops in BIST circuit 3.

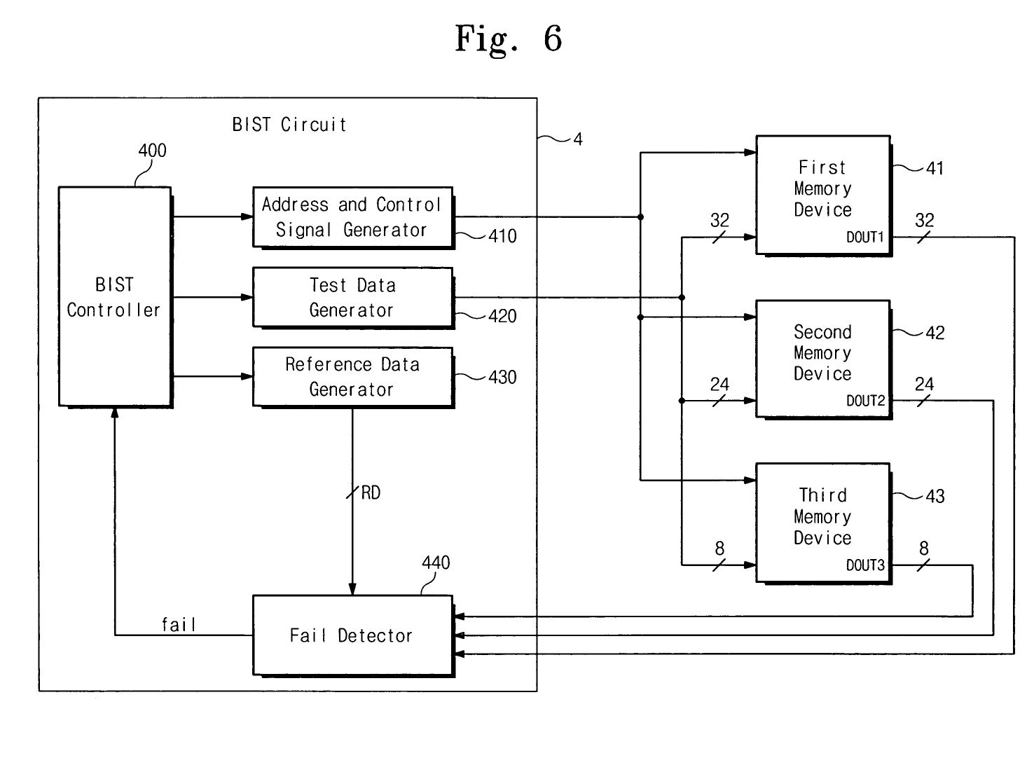

FIG. 6 illustrates a schematic diagram of a BIST circuit according to another exemplary embodiment of the present invention. The BIST circuit 4 may determine whether memory failure occurs in first memory device 41, second memory device 42 and/or third memory device 43.

In an exemplary embodiment of the present invention, as shown in FIG. 6, the first memory device 41, second memory device 42 and third memory device 43 may each have a different number of I/O terminals, respectively. For example, in FIG. 6, the first memory device 41, second memory device 42 and third memory device 43 may have 32, 24 and 8 I/O terminals, respectively. Further, equivalent test data may be written to corresponding addresses of first memory device 41, second memory device 42 and third memory device 43. For example, D1N1[0]=D1N2[0]=D1N3[0], D1N1[1]=D1N2[1]=D1N3[1], . . . , D1N1[7]=D1N2[7]=D1N3[7], D1N1[8]=D1N2[8]=D1N3[8], . . . , D1N1[23]=D1N2[23]=D1N3[23], etc.

In an exemplary embodiment of the present invention, referring to FIG. 6, the BIST circuit 4 may include a BIST controller 400, an address and control signal generator 410, a test data generator 420, a reference data generator 430 and a fail detector 330. The BIST circuit 4 may determine whether memory failure occurs in at least one of the first memory device 41, second memory device 42 and third memory device 43 without a comparator.

In an exemplary embodiment of the present invention, the BIST controller 400, the address and control signal generator 410, and the test data generator 420 may function similarly to to the BIST controller 100, address and control signal generator 110, and test data generator 120, respectively, of FIG. 1.

The reference data generator 430 may generate RD which may be compared with data read from the first memory device 41, second memory device 42 and third memory device 43. In FIG. 6, the reference data generator 430 may generate RD same equivalent with the test data generated in the test data generator 420.

In another exemplary embodiment of the present invention, the test data may be written to the first memory device 41, and may not be written to the second memory device 42 and the third memory 43. Therefore, RD[24]=D1N1[24], . . . , RD[31]=D1N1[31].

In another exemplary embodiment of the present invention, the fail detector 440 may determine whether data read from corresponding addresses of first memory device 41, second memory device 42 and third memory device 43 are equivalent with the RD. Specifically, the fail detector 440 may determine whether DOUT1[24]=RD[24], . . . , DOUT1[31]=RD[31]. If the fail detector 440 determines any compared data as not being equal, a fail signal may be outputted by the fail detector 440.

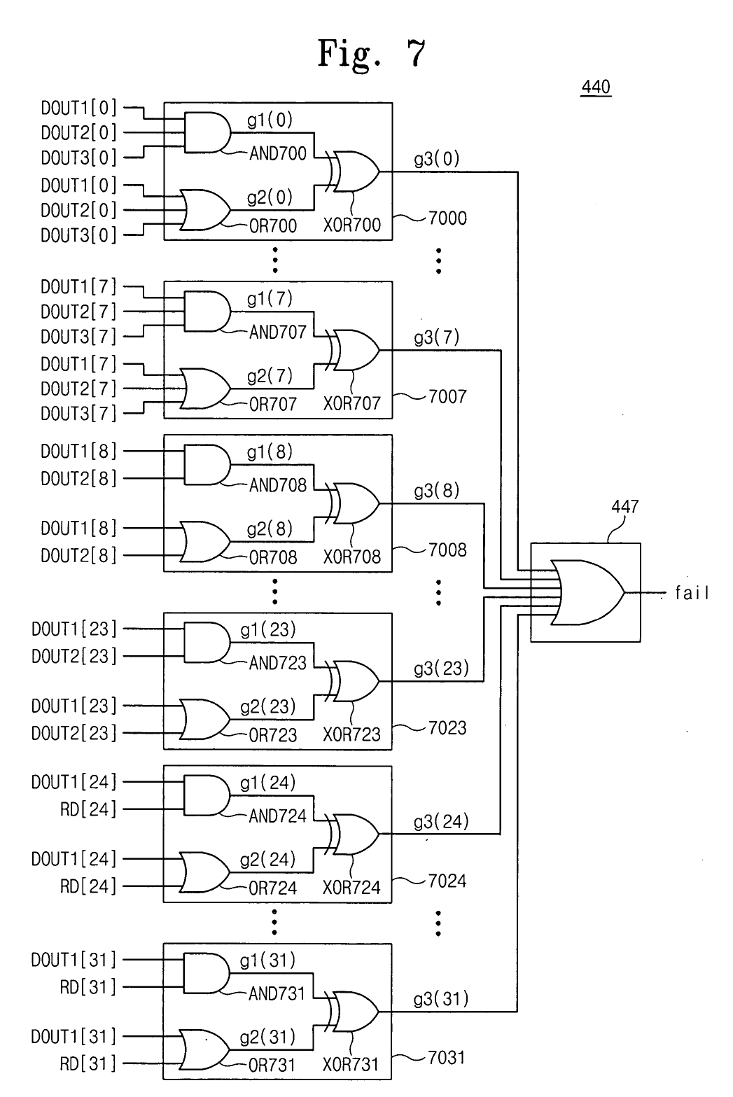

FIG. 7 illustrates a schematic circuit diagram of the fail detector of FIG. 6 according to an exemplary embodiment of the present invention. The fail detector 440 may include CLC 7000-7031, and an OR gate 447. The CLC 7000-7031 may receive data read from corresponding addresses of the first memory 41, second memory device 42 and third memory device 43. The OR gate 447 may receive data read from the CLC 7000-7031 in order to determine whether to generate a fail signal.

In an exemplary embodiment of the present invention, the CLC 7000-7031 may include AND gates AND700-AND731, OR gates OR700-OR731, and XOR gates XOR700-XOR731, respectively. The OR gate 447 may include a single OR gate.

In another exemplary embodiment of the present invention, as shown in FIG. 7, the CLC 7008 may receive only DOUT1[8] and DOUT2 [8], and not DOUT3[8]. This may occur since the third memory device 43 of FIG. 6 has 8 I/O terminals. Therefore, only DOUT3[0]-DOUT3[7] may be read from third memory device 43.

In another exemplary embodiment of the present invention, CLC 7024 may receive only DOUT1[24], and not DOUT2[24] and/or DOUT3[24]. This may occur since both the second memory device 42 and the third memory device 43 no more than 24 I/O terminals. Therefore, only DOUT3[0]-DOUT3[7] may be read from the third memory device 43. Similarly, only DOUT2[0]-DOUT2[23] may be read from second memory device 42. Since CLC 7024 may receive only data read from first memory device 41, no comparison may be possible with either the second memory device 42 and/or the third memory device 43. The CLC 7024 may receive the reference data RD[24] from the reference data generator 430 in order to determine whether the reference data RD[24] is equivalent to DOUT1[24]. Similar comparisons may be performed between RD[25]-RD[31] and DOUTI[25]-DOUT1[31], respectively.

In another exemplary embodiment of the present invention, the OR gate 447 may output a logic “1” as a fail signal when at least one of CLC 7000-7031 outputs logic “1”.

In another exemplary embodiment of the present invention, the number of I/O terminals of first memory device 41, second memory device 42, and third memory device 43 may not be equal. The BIST circuit 4 may determine whether the first memory device 41, second memory device 42, and/or third memory device 43, each having different numbers of I/O terminals, have memory failure.

In another exemplary embodiment of the present invention, the BIST circuit 4 may simultaneously determine whether memory failure exists in at least one of first memory device 41, second memory device 42, and/or third memory device 43. Simultaneous memory failure testing may reduce the test time of the BIST circuit 4. In this exemplary embodiment, a comparator may not be used. Further, in this exemplary embodiment, a fail detector, for example fail detector 440 of FIG. 6, may be used. The use of a fail detector instead of a comparator may reduce the number of flipflops in the BIST circuit 4.

The exemplary embodiments of the present invention being thus described, it will be obvious that the same may be varied in many ways. For example, above exemplary embodiments have been described with respect to testing three semiconductor memory devices (i.e. first memory device (31,41), second memory device (32,42), and third memory device (33,44)). However, the above described BIST circuits may test any number of semiconductor memory devices simultaneously. Further, numbers of I/O terminals have been above described in exemplary embodiments as having 32, 24, and/or 8 I/O terminals. However, semiconductor memory devices to be tested may have any number of I/O terminals. Also, a fail signal has been above-described as indicating failure when the fail signal has a logic “1”. However, any logic level, which may include logic “0” and/or logic “1”, may be adapted to indicate memory failure to the BIST circuit.

Such variations are not to be regarded as departure from the spirit and scope of the exemplary embodiments of the present invention, and all such modifications as would be obvious to one skilled in the art are intended to be included within the scope of the following claims.

1. A semiconductor device for testing memory, comprising:
a BIST controller for testing a plurality of memory devices;
an address and control signal generator for generating address and control signals for reading data from the plurality of memory devices;
a test data generator for generating test data; and
a fail detector for determining memory failure.

2. The semiconductor device of claim 1, wherein the plurality of memory devices each have the same number of input/output terminals.

3. The semiconductor device of claim 1, wherein at least one of the plurality of memory devices has a first number of input/output (I/O) terminals, the first number being greater than or equal to a number of I/O terminals of any other memory device of the plurality of memory devices.

4. The semiconductor device of claim 1, wherein the fail detector outputs logic “1” as a fail signal when data read from corresponding addresses of at least two of the plurality of memory devices are not equal.

5. The semiconductor device of claim 1, wherein the fail detector comprises:
a plurality of combinational logic circuits (CLC) for receiving data read from corresponding addresses of the plurality of memory devices, each of the plurality of CLC outputting a first result based on the received data; and
a first OR gate for receiving the first results and outputting a second result based on the first results.

6. The semiconductor device of claim 5, wherein at least one of the first results have logic “1” when indicating memory failure.

7. The semiconductor device of claim 5, wherein the second result has logic “1” when indicating memory failure.

8. The semiconductor device of claim 5, wherein each of the plurality of CLC comprises:
AND and second OR gates each for receiving data from corresponding addresses of the plurality of memory devices; and
an XOR gate for receiving outputs from the AND and second OR gates and generating a first fail signal based on the received outputs.

9. The semiconductor device of claim 1, wherein the fail detector outputs logic “0” as a fail signal when data read from corresponding addresses of at least two of the plurality of memory devices are not equal.

10. A semiconductor device for testing at least one of a plurality of memory devices, comprising:
a BIST controller for testing a plurality of memory devices;
an address and control signal generator for generating address and control signals for reading data from the plurality of memory devices;
a test data generator for generating test data;
a reference data generator for generating reference data; and
a fail detector for determining memory failure.

11. The semiconductor device of claim 10, wherein the fail detector compares data received from corresponding addresses of the plurality of memory devices.

12. The semiconductor device of claim 10, wherein the fail detector compares data received from corresponding addresses of the plurality of memory devices with the reference data.

13. The semiconductor device of claim 10, wherein at least one of the plurality of memory devices has a first number of input/output (I/O) terminals, the first number being greater than or equal to a number of I/O terminals of any other memory device of the plurality of memory devices.

14. The semiconductor device of claim 13, wherein the fail detector compares data received the the at least two of the plurality of memory devices with the reference data.

15. The semiconductor device of claim 12, wherein the fail detector outputs logic “1” as a fail signal when data read from corresponding addresses of at least one of the plurality of memory devices and the reference data are not equal.

16. The semiconductor device of claim 12, wherein the fail detector outputs logic “0” as a fail signal when data read from corresponding addresses of at least one of the plurality of memory devices and the reference data are not equal.

17. A method of determining memory failure, comprising:
writing data to a plurality of memory devices;
reading the data from the plurality of memory devices;
comparing corresponding addresses of the read data simultaneously;
outputting a single fail signal when the comparing determines at least one of the read data from the plurality of memory devices as not being equal.

18. A semiconductor device for performing the method of claim 17.

19. A semiconductor device for testing memory, comprising:
a BIST controller for testing a plurality of memory devices;
an address and control signal generator for generating address and control signals for reading data from the plurality of memory devices;
a test data generator for generating test data;
a reference data generator for generating reference data;
a selection circuit for selecting the read data from one of the plurality of memory devices; and
a comparator for comparing the read data from one of the plurality of memory devices with the reference data.

20. A semiconductor device for testing memory, comprising:
a BIST controller for testing a plurality of memory devices;
an address and control signal generator for generating address and control signals for reading data from the plurality of memory devices;
a test data generator for generating test data; and
a single comparison unit for determining memory failure in at least two of the plurality of memory devices.

21. A method of determining memory failure, comprising:
writing data to a plurality of memory devices;
reading the data from the plurality of memory devices;
comparing corresponding addresses of the read data of at least two of the plurality of memory devices in a single comparison unit.
